(19) United States
(12) Patent Application Publication
(10) Pub. No.: US 2015/0221825 A1
(43) Pub. Date: Aug. 6, 2015

(54) SEMICONDUCTOR LIGHT EMITTING DEVICE AND SEMICONDUCTOR LIGHT EMITTING DEVICE PACKAGE

(71) Applicant: SAMSUNG ELECTRONICS CO., LTD., Suwon-Si (KR)

(72) Inventors: Geun-Woo KO, Suwon-si (KR); Nam Goo CHA, Ansan-si (KR); Hyun Seong KUM, Yongin-si (KR)

(21) Appl. No.: 14/521,423

(22) Filed: Oct. 22, 2014

(30) Foreign Application Priority Data
Feb. 4, 2014 (KR) 10-2014-0012463

(51) Int. Cl. H01L 33/24; H01L 33/38; H01L 33/54; H01L 33/46; H01L 33/62; H01L 33/58

(52) U.S. Cl. CPC H01L 33/24; H01L 33/62; H01L 33/58; H01L 33/54; H01L 33/46; H01L 33/382

(57) ABSTRACT

A semiconductor light emitting device includes a substrate, a first conductivity-type semiconductor base layer disposed on the substrate, a plurality of light emitting nanostructures, a transparent electrode layer, and a first electrode. The plurality of light emitting nanostructures are disposed to be spaced apart from one another on the first conductivity-type semiconductor base layer and include a first conductivity-type semiconductor core, an active layer, and a second conductivity-type semiconductor layer, respectively. The transparent electrode layer is disposed on the second conductivity-type semiconductor layer and between the plurality of light emitting nanostructures. The first electrode is electrically connected to the second conductivity-type semiconductor layer by penetrating the substrate.

### CROSS-REFERENCE TO RELATED APPLICATION

This application claims benefit of priority to Korean Patent Application No. 10-2014-0012463 filed on Feb. 4, 2014, with the Korean Intellectual Property Office, the entire content of which is incorporated herein by reference.

### TECHNICAL FIELD

The present disclosure relates to a semiconductor light emitting device and a semiconductor light emitting device package.

### BACKGROUND

Light emitting diodes (LEDs) having many advantages such as a long lifespan, low power consumption, a fast response speed, environmental friendliness, and the like, compared to related art light sources, have been widely seen as next generation lighting sources, and have come to prominence as important sources of light in various products, such as general lighting devices and in the backlights of display devices. In particular, LEDs based on Group III nitrides, such as GaN, AlGaN, InGaN, InAlGaN, and the like, commonly serve as semiconductor light emitting devices outputting blue or ultraviolet light.

Recently, as LEDs have come into widespread use, the utilization thereof has extended to light sources for application to high current and high output devices. Demand for LEDs for application to high current and high output devices has spurred ongoing research into improvements in light emitting characteristics in the art. In particular, in order to increase luminous efficiency through enhancements in crystallinity and increases in light emitting areas, semiconductor light emitting devices having light emitting nanostructures and a manufacturing technique therefor have been proposed.

### SUMMARY

An aspect of the present disclosure may provide a semiconductor light emitting device in which loss is minimized in a light emitting area and heat is easily dissipated.

An aspect of the present disclosure may also provide a semiconductor light emitting device package allowing for simplified processes and miniaturization.

One aspect of the present disclosure relates to a semiconductor light emitting device including a substrate, a first conductivity-type semiconductor base layer disposed on the substrate, a plurality of light emitting nanostructures, a transparent electrode layer and a first electrode. The plurality of light emitting nanostructures are disposed to be spaced apart from one another on the first conductivity-type semiconductor base layer and include a first conductivity-type semiconductor core, an active layer, and a second conductivity-type semiconductor layer, respectively. The transparent electrode layer is disposed on the second conductivity-type semiconductor layer and between the plurality of light emitting nanostructures. The first electrode is electrically connected to the second conductivity-type semiconductor layer by penetrating the substrate.

The first electrode may extend between the plurality of light emitting nanostructures from a lower surface of the substrate.

The first electrode may include a through portion penetrating the substrate, the first conductivity-type semiconductor base layer, the transparent electrode layer, and a portion of the plurality of light emitting nanostructures; and a contact portion connecting the through portion and the transparent electrode layer.

The contact portion may surround the through portion between the plurality of light emitting nanostructures on an upper side of the transparent electrode layer.

The through portion may be electrically isolated from the substrate and the first conductivity-type semiconductor base layer by an insulating layer.

The insulating layer may surround lateral surfaces of the through portion.

The first electrode may be in contact with the transparent electrode layer by penetrating the substrate and the first conductivity-type semiconductor base layer.

The plurality of light emitting nanostructures may not be disposed on the first electrode and the transparent electrode layer may be disposed to be flat on the first electrode.

The semiconductor light emitting device may further include a second electrode connected to the first conductivity-type semiconductor base layer by penetrating the substrate.

The semiconductor light emitting device may further include a mask layer disposed on the first conductivity-type semiconductor base layer and having a plurality of openings exposing the first conductivity-type semiconductor base layer, and the mask layer may be a distributed Bragg Reflector (DBR) layer.

The substrate may be a silicon (Si) substrate.

The semiconductor light emitting device may further include a filler layer filling spaces between the plurality of light emitting nanostructures, wherein the first electrode may penetrate the filler layer, and an upper surface of the first electrode may substantially be coplanar with an upper surface of the filler layer.

An upper surface of the through portion of the first electrode may be above an upper surface of the light emitting nanostructures.

An upper surface of the through portion of the first electrode may be at the same vertical level as a vertical level of an upper surface of the light emitting nanostructures.

Another aspect of the present disclosure encompasses a semiconductor light emitting device package including a package board and a semiconductor light emitting device disposed on the package board. The semiconductor light emitting device includes a substrate, a first conductivity-type semiconductor base layer disposed on the substrate, a plurality of light emitting nanostructures, a transparent electrode layer, and first and second electrodes. The plurality of light emitting nanostructures are disposed to be spaced apart from one another on the first conductivity-type semiconductor base layer and include a first conductivity-type semiconductor core, an active layer, and a second conductivity-type semiconductor layer, respectively. The transparent electrode layer is disposed on the second conductivity-type semiconductor layer and between the plurality of light emitting nanostructures. The first electrode is electrically connected to the second conductivity-type semiconductor layer by penetrating through the substrate. The second electrode is electrically connected to the first conductivity-type semiconductor base layer by penetrating through the substrate. The semiconductor light emitting device is disposed on the package board such that a light emitting surface faces upwards and the first and second electrodes are connected to the package board.

The semiconductor light emitting device package may further include a lens encapsulating the semiconductor light emitting device.

The package board may include at least one via hole.

Still another aspect of the present disclosure relates to a semiconductor light emitting device package including a package body, a lead frame, and a semiconductor light emitting device disposed on the lead frame in the package body and electrically connected to the lead frame. The semiconductor light emitting device includes a substrate, a first conductivity-type semiconductor base layer disposed on the substrate, a plurality of light emitting nanostructures disposed to be spaced apart from one another on the first conductivity-type semiconductor base layer and including a first conductivity-type semiconductor core, an active layer, and a second conductivity-type semiconductor layer, respectively, a transparent electrode layer disposed on the second conductivity-type semiconductor layer and between the plurality of light emitting nanostructures, a first electrode electrically connected to the second conductivity-type semiconductor layer by penetrating the substrate, and a second electrode electrically connected to the first conductivity-type semiconductor base layer by penetrating the substrate. The semiconductor light emitting device is disposed in a flipchip structure in which both the first and second electrodes are disposed downwardly on the lead frame.

The lead frame may include a pair of lead frames electrically connected the first and second electrodes of the semiconductor light emitting device, respectively.

The semiconductor light emitting device package may have an encapsulant including a light-transmissive material. The package body may have a cup shape to reflect light emitted from the semiconductor light emitting device. The encapsulant may be disposed in the cup shape to encapsulate the semiconductor light emitting device.

### BRIEF DESCRIPTION OF DRAWINGS

The above and other aspects, features and other advantages of the present disclosure will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a cross-sectional view schematically illustrating a semiconductor light emitting device according to an exemplary embodiment of the present inventive concept.

FIG. 2 is a cross-sectional view schematically illustrating a semiconductor light emitting device according to an exemplary embodiment of the present inventive concept.

FIGS. 3A through 3L are cross-sectional views schematically illustrating a method of manufacturing a semiconductor light emitting device according to an exemplary embodiment of the present inventive concept.

FIG. 4 is a cross-sectional view schematically illustrating a semiconductor light emitting device according to an exemplary embodiment of the present inventive concept.

FIGS. 5 and 6 are views illustrating examples of packages employing a semiconductor light emitting device according to an exemplary embodiment of the present inventive concept.

FIGS. 7 and 8 are examples of backlight units employing a semiconductor light emitting device according to an exemplary embodiment of the present inventive concept.

FIG. 9 is a view illustrating an example of a lighting device employing a semiconductor light emitting device according to an exemplary embodiment of the present inventive concept.

FIG. 10 is a view illustrating an example of a headlamp employing a semiconductor light emitting device according to an exemplary embodiment of the present inventive concept.

### DETAILED DESCRIPTION

Hereinafter, exemplary embodiments of the present inventive concept will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

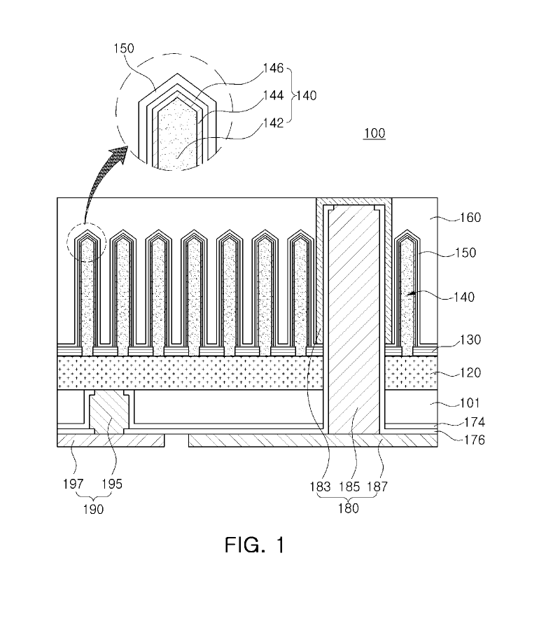

FIG. 1 is a cross-sectional view schematically illustrating a semiconductor light emitting device according to an exemplary embodiment of the present inventive concept.

Referring to FIG. 1, a semiconductor light emitting device 100 may include a substrate 101, and a first conductivity-type semiconductor base layer 120, a mask layer 130, light emitting nanostructures 140, a transparent electrode layer 150, and a filler layer 160 formed on the substrate 101. Each light emitting nanostructure 140 may include a first conductivity-type semiconductor core 142, an active layer 144, and a second conductivity-type semiconductor layer 146 grown on the first conductivity-type semiconductor base layer 120. The semiconductor light emitting device 100 may further include a first electrode 180 electrically connected to the second conductivity-type semiconductor layer 146, and a second electrode 190 electrically connected to the first conductivity-type semiconductor base layer 120 through the substrate 101.

In the present disclosure, unless otherwise mentioned, directionality in terms such as ‘upper portion’, ‘upper surface’, ‘lower portion’, ‘lower surface’, ‘lateral surface’, and the like, is determined based on the drawings, and in actuality, the terms may be changed according to a direction in which a device is disposed.

The substrate 101 may be provided as a semiconductor growth substrate and may be formed of an insulating material, a conductive material, or a semiconductive material, such as sapphire, SiC, MgAl₂O₄, MgO, LiAlO₂, LiGaO₂, GaN, or the like. When the substrate 101 is formed of silicon (Si), it may be more appropriate for increasing a diameter and relatively low in price, thereby facilitating mass-production. Also, in case of silicon (Si), mechanical machining such as etching may be facilitated. In order to grow a nitride-based compound, for example, the (111) plane of a silicon substrate may be used.

According to an exemplary embodiment of the present inventive concept, a depression and protrusion pattern may be formed on a surface of the substrate 101 to enhance light extraction efficiency. Also, according to an exemplary embodiment of the present inventive concept, a buffer layer (not shown) may be further disposed on the substrate 101 in order to enhance crystallinity of the first conductivity-type semiconductor base layer 120. The buffer layer may be formed of, for example, AlGaN or GaN grown at a low temperature without being doped.

The first conductivity-type semiconductor base layer 120 may be disposed on the substrate 101. The first conductivity-type semiconductor base layer 120 may be formed of a Group III-V compound, for example, GaN. The first conductivity-type semiconductor base layer 120 may be, for example, n-GaN doped with an n-type impurity.

In an exemplary embodiment of the present inventive concept, the first conductivity-type semiconductor base layer 120 may be commonly connected to one side of the respective light emitting nanostructures 140 to serve as a contact electrode, as well as providing crystal planes for growing the first conductivity-type semiconductor core 142.

The mask layer 130 may be disposed on the first conductivity-type semiconductor base layer 120. The mask layer 130 may be formed of a silicon oxide or a silicon nitride. For example, the mask layer 130 may be formed of at least one of SiOₓ, SiOₓN_{y}, SiₓN_{y}, Al₂O₃, TiN, AlN, ZrO, TiAlN, and TiSiN. In particular, the mask layer 130 may be a Distributed Bragg Reflector (DBR) layer or an omni-directional reflector (ODR). In this case, the mask layer 130 may have a structure in which layers having different refractive indices are alternately and repeatedly disposed. However, the present inventive concept is not limited thereto and, according to an exemplary embodiment of the present inventive concept, the mask layer 130 may be a monolayer formed of at least one of, for example, SiO, SiON, SiN, Al₂O₃, TiN, AlN, ZrO, TiAlN, and TiSiN.

The mask layer 130 may include a plurality of openings exposing portions of the first conductivity-type semiconductor base layer 120. The diameter, length, position, and growth conditions of the light emitting nanostructures 140 may be determined according to the size of the plurality of openings. The plurality of openings may have various shapes such as a circular shape, a quadrangular shape, a hexagonal shape, or the like.

The plurality of light emitting nanostructures 140 may be disposed in positions corresponding to the plurality of openings. The light emitting nanostructures 140 may have a core-shell structure including the first conductivity-type semiconductor core 142 grown on regions of the first conductivity-type semiconductor base layer 120 exposed by the plurality of openings, the active layer 144 sequentially formed on a surface of the first conductivity-type semiconductor core 142, and the second conductivity-type semiconductor layer 146.

The first conductivity-type semiconductor core 142 and the second conductivity-type semiconductor layer 146 may respectively be formed of semiconductor doped with an n-type impurity and a p-type impurity, but the present inventive concept is not limited thereto and, conversely, the first conductivity-type semiconductor core 142 and the second conductivity-type semiconductor layer 146 may respectively be formed of p-type and n-type semiconductor. The first conductivity-type semiconductor core 142 and the second conductivity-type semiconductor layer 146 may be formed of a nitride semiconductor, e.g., a material having a composition of AlₓIn_{y}Ga_{1-x-y}N (0≦x≦1, 0≦y≦1, 0≦x+y≦1). Each of the semiconductor layers 142 and 146 may be configured as a single layer, or may include a plurality of layers having different characteristics such as different doping concentrations, compositions, and the like. Here, the first conductivity-type semiconductor core 142 and the second conductivity-type semiconductor layer 146 may be formed of an AlInGaP or AlInGaAs semiconductor, besides a nitride semiconductor. In an exemplary embodiment of the present inventive concept, the first conductivity-type semiconductor core 142 may be formed of n-GaN doped with silicon (Si) or carbon (C), and the second conductivity-type semiconductor layer 146 may be formed of p-GaN doped with magnesium (Mg) or zinc (Zn).

As illustrated (e.g., in FIG. 1), the width of the first conductivity-type semiconductor core 142 may be greater than widths of the openings of the mask layer 130, but the present inventive concept is not limited thereto.

The active layer 144 may be disposed on a surface of the first conductivity-type semiconductor core 142. The active layer 144 may be a layer emitting light having a predetermined level of energy according to electron-hole recombination and formed of a single material such as InGaN, or the like, or may have a multi-quantum well (MQW) structure in which quantum barrier layers and quantum well layers are alternately disposed, and, for example, in case of a nitride semiconductor, an GaN/InGaN structure may be used. When the active layer 144 includes InGaN, since the content of indium (In) is increased, crystal defects due to lattice mismatches may be reduced and internal quantum efficiency of the semiconductor light emitting device 100 may be increased. Also, an emission wavelength may be adjusted according to the content of indium (In).

The number of light emitting nanostructures 140 included in the semiconductor light emitting device 100 may not be limited to the number illustrated in the drawings and the semiconductor light emitting device 100 may include, for example, tens to millions of light emitting nanostructures 140. The light emitting nanostructures 140 according to an embodiment of the present inventive concept may include a lower hexagonal prism region and an upper hexagonal pyramid region. In this case, the first conductivity-type semiconductor core 142 may have lower m planes and upper r planes, or may have different crystal planes. Thicknesses of the active layer 144 and the second conductivity-type semiconductor layer 146 formed in the upper portions thereof may be different according to the crystal planes. For example, thicknesses of the active layer 144 and the second conductivity-type semiconductor layer 146 on the m planes may be greater than thicknesses of the active layer 144 and the second conductivity-type semiconductor layer 146 on the r planes.

Also, according to an exemplary embodiment of the present inventive concept, the light emitting nanostructures 140 may be pyramid shaped or a pillar shaped. Since the light emitting nanostructures 140 have a three-dimensional shape, a light emitting surface area may be relatively large, increasing luminous efficiency.

The transparent electrode layer 150 may be electrically connected to the second conductivity-type semiconductor layer 146. The transparent electrode layer 150 may cover upper surfaces and lateral surfaces of the light emitting nanostructure 140 and may be connected between adjacent light emitting nanostructures 140. The transparent electrode layer 150 may be formed of, for example, indium tin oxide (ITO), aluminum zinc oxide (AZO), indium zinc oxide (IZO), ZnO, GZO (ZnO:Ga), In₂O₃, SnO₂, CdO, CdSnO₄, or Ga₂O₃.

The filler layer 160 may be disposed on the light emitting nanostructures 140 and the transparent electrode layer 150. The filler layer 160 may fill spaces between adjacent light emitting nanostructures 140 and may be disposed to cover the light emitting nanostructures 140 and the transparent electrode layer 150 on the light emitting nanostructures 140. According to an exemplary embodiment of the present inventive concept, an upper surface of the filler layer 160 may be formed to be uneven along the light emitting nanostructures 140.

The filler layer 160 may be formed of a light-transmissive insulating material and include, for example, SiO₂, SiNₓ, Al₂O₃, HfO, TiO₂, or ZrO. According to an exemplary embodiment of the present inventive concept, a passivation layer (not shown) may be disposed on the filler layer 160.

The first and second electrodes 180 and 190 may be disposed to penetrate through the substrate 101 from a lower surface of the substrate 101 so as to be electrically connected to second conductivity-type semiconductor layer 146 and the first conductivity-type semiconductor base layer 120, respectively.

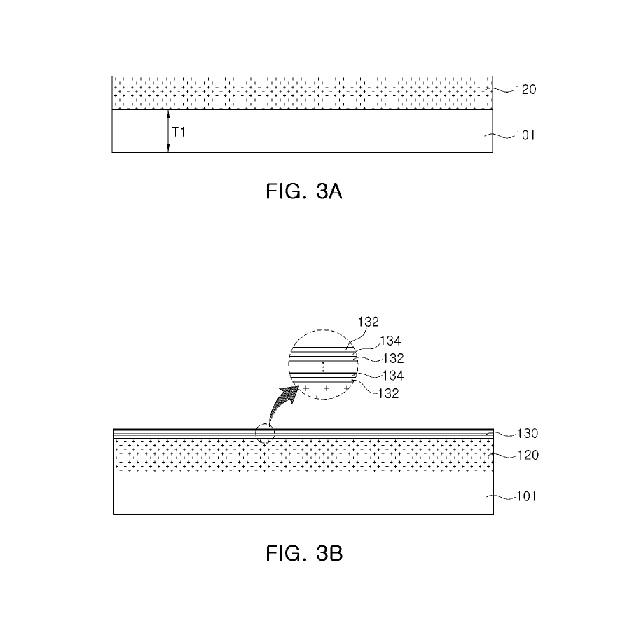

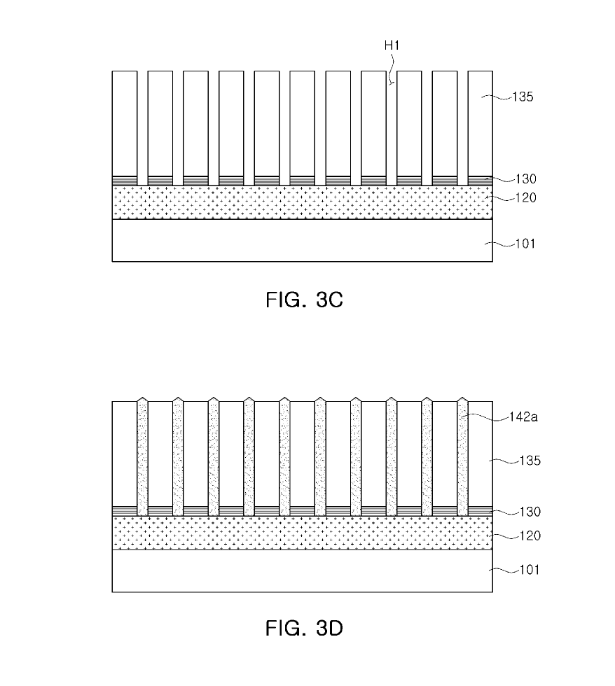

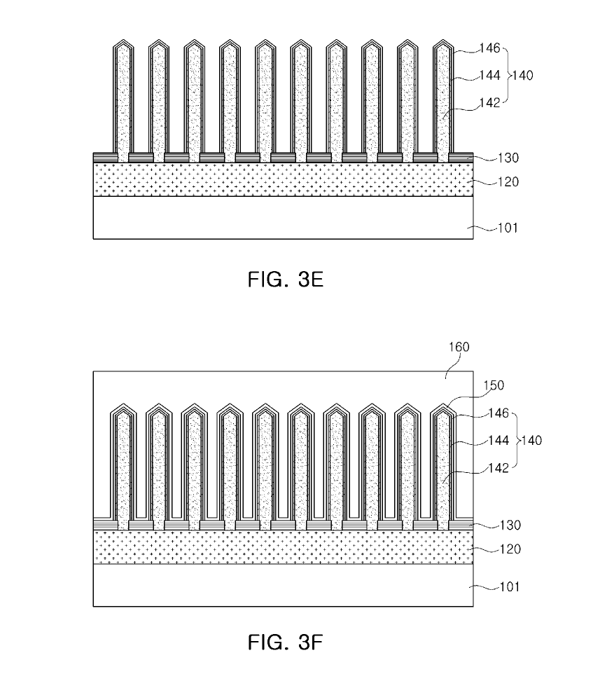

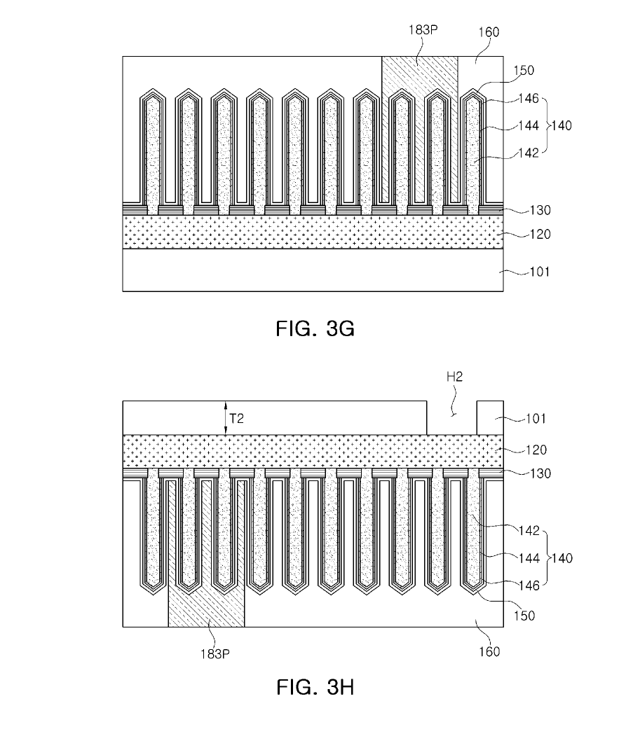

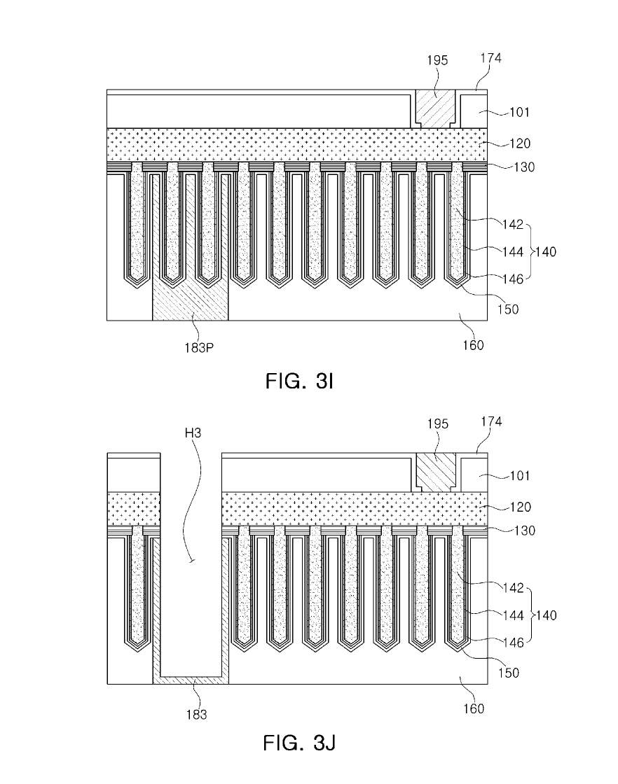

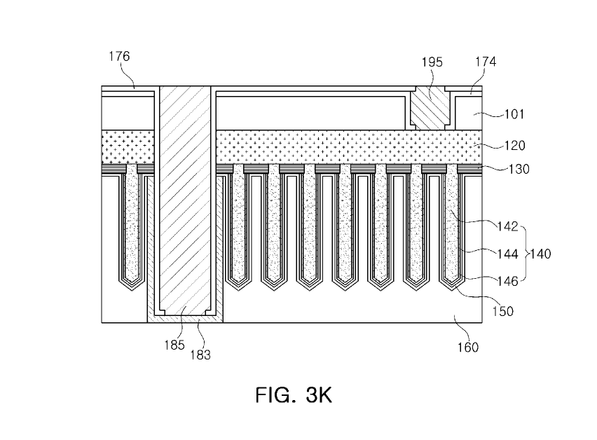

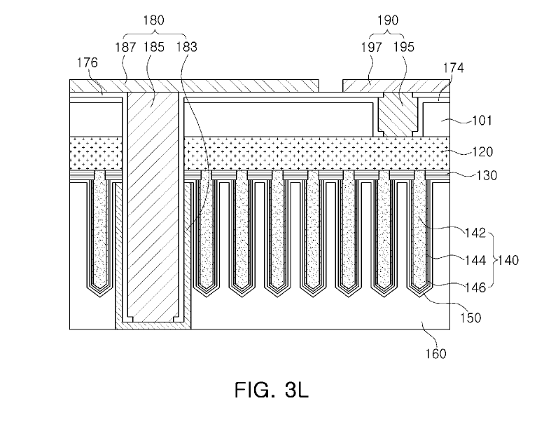

The first electrode 180 may include a contact portion 183, a first through portion 185, and a first bonding portion 187. The contact portion 183 may be disposed to surround the first through portion 185 above the mask layer 130, such that the first through portion 185 and the transparent electrode layer 150 may be connected. The contact portion 183 may be used as an etch stop layer during a process of forming the first through portion 185. This will be described in detail with reference to FIG. 3J hereinbelow. An upper surface of the contact portion 183 may be substantially coplanar with an upper surface of the filler layer 160. The first through portion 185 may extend from the first bonding portion 187 disposed on a lower surface of the substrate 101, penetrate through the substrate 101 and the first conductivity-type semiconductor base layer 120, and extend between the light emitting nanostructures 140. An upper surface of the first through portion 185 may be above an upper surface of the light emitting nanostructures 140. The first bonding portion 187 may be disposed on a lower surface of the substrate 101, and when the semiconductor light emitting device 100 is mounted on an external device such as a package board, the first bonding portion 187 may connect the semiconductor light emitting device 100 to the external device such that the semiconductor light emitting device 100 is electrically connected to the external device.

The second electrode 190 may include a second through portion 195 and a second bonding portion 197. The second through portion 195 may extend from the second bonding portion 197 disposed on a lower surface of the substrate 101, penetrate through the substrate 101, and be connected to the first conductivity-type semiconductor base layer 120. The second bonding portion 197 may be disposed on a lower surface of the substrate 101, and when the semiconductor light emitting device 100 is mounted on an external device such as a package board, the second bonding portion 197 allow the semiconductor light emitting device 100 to be electrically connected to the external device, together with the first bonding portion 187.

The first and second electrodes 180 and 190 may be disposed to be spaced apart from one another in a lower portion of the semiconductor light emitting device, and the first and second through portions 185 and 195 may have, for example, a cylindrical shape. However, the number, size, shape, and disposition of the first and second electrodes 180 and 190 may be variously modified. For example, the size of the first and second electrodes 180 and 190 may be variously modified in consideration of a size, a light emitting area, a current flow, or the like, of the semiconductor light emitting device 100, and a plurality of first electrodes 180 may be disposed to be spaced apart from one another.

The first and second electrodes 180 and 190 may be formed as a monolayer or may have a multilayer structure of a conductive material. For example, the first and second electrodes 180 and 190 may include one or more of Au, Ag, Cu, Zn, Al, In, Ti, Si, Ge, Sn, Mg, Ta, Cr, W, Ru, Rh, Ir, Ni, Pd, Pt, and an alloy thereof.

The first and second electrodes 180 and 190 may be electrically insulated from the substrate 101, or the like, by first and second insulating layers 174 and 176. The first insulating layer 174 may be disposed between the second through portion 195 and the substrate 101. The second insulating layer 176 may be disposed to surround the lateral surfaces of the first through portion 185 to electrically separate the first through portion 185 from the substrate 101 and the first conductivity-type semiconductor base layer 120. Also, the second insulating layer 176 may also extend to upper side of the mask layer 130 along the first through portion 185, but the present inventive concept is not limited thereto.

Since the semiconductor light emitting device 100 according to an exemplary embodiment of the present inventive concept does not employs wire bonding, a light emitting area may be secured by adjusting a size of the first electrode 180, and since the first and second electrodes 180 and 190 formed of a conductive material are disposed below the light emitting nanostructures 140, a heat dissipation effect may be enhanced.

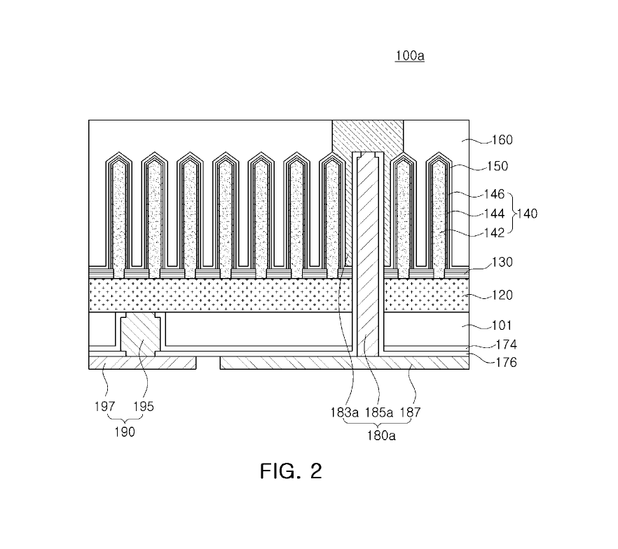

FIG. 2 is a cross-sectional view schematically illustrating a semiconductor light emitting device according to an exemplary embodiment of the present inventive concept.

In the following drawings, reference numerals identical to those of FIG. 1 denote the same components, so redundant descriptions will be omitted.

Referring to FIG. 2, a semiconductor light emitting device 100a may include a substrate 101, and a first conductivity-type semiconductor base layer 120, a mask layer 130, a light emitting nanostructure 140, a transparent electrode layer 150, and a filler layer 160 formed on the substrate 101. The light emitting nanostructure 140 may include a first conductivity-type semiconductor core 142, an active layer 144, and a second conductivity-type semiconductor layer 146 grown on the first conductivity-type semiconductor base layer 120. The semiconductor light emitting device 100a may further include a first electrodes 180a electrically connected to the second conductivity-type semiconductor layer 146, and a second electrode 190 electrically connected to the first conductivity-type semiconductor base layer 120 through the substrate 101.

In an exemplary embodiment of the present inventive concept, the first electrode 180a may include a contact portion 183a and a first through portion 185a having different shapes from shapes of the contact portion 183 and the first through portion 185 according to the exemplary embodiment of FIG. 1.

Lateral surfaces of the contact portion 183a may be formed along the light emitting nanostructures 140, and thus, the contact portion 183a may be formed to be in contact with the transparent electrode layer 150 on the light emitting nanostructures 140. According to an exemplary embodiment of the present inventive concept, only a portion of the lateral surfaces of the contact portion 183a may have an uneven surface along the light emitting nanostructures 140 and the other portions thereof may have a flat surface between the light emitting nanostructures 140. The first through portion 185a may be disposed within the contact portion 183a and may have a size (e.g., width) similar to that of the light emitting structures 140. An upper surface of the first through portion 185a may be substantially at the same vertical level as that of an upper surface of the light emitting nanostructures 140. According to an exemplary embodiment of the present inventive concept, several first through portions 185a may be disposed within the contact portion 183a, and a second insulating layer 176 may be disposed on a side wall of the first through portion 185a.

FIGS. 3A through 3L are cross-sectional views schematically illustrating a method of manufacturing a semiconductor light emitting device according to an exemplary embodiment of the present inventive concept. In FIGS. 3A through 3L, the method of manufacturing a semiconductor light emitting device will be described based on the semiconductor light emitting device of FIG. 1, but semiconductor light emitting devices of any other exemplary embodiments of the present inventive concept may also be manufactured in a similar manner.

Referring to FIG. 3A, a substrate 101 may be prepared, and a first conductivity-type semiconductor may be grown on the substrate 101 to form a first conductivity-type semiconductor base layer 120.

The first conductivity-type semiconductor base layer 120 may provide a crystal growth surface allowing the light emitting nano structures 140 (refer to FIG. 1) to grow thereon, and may be a structure electrically connecting one sides (e.g., a same side) of the light emitting nanostructures 140. Thus, the first conductivity-type semiconductor base layer 120 may be formed as a semiconductor single crystal having electrical conductivity, and in this case, the substrate 101 may be a substrate for crystal growth. In particular, a silicon (Si) substrate may be used as the substrate 101 in order to facilitate etching, or the like, in a follow-up process. The substrate 101 may have a first thickness T1 and may become thinner during a follow-up process.

Referring to FIG. 3B, a mask layer 130 may be formed on the first conductivity-type semiconductor base layer 120.

The mask layer 130 may include a plurality of alternate first and second layers 132 and 134. The mask layer 130 may serve as a reflective layer to redirect light, which is part of light generated by the active layer 142 and moves in a direction toward the substrate 101, to an upper side of the light emitting nanostructures 140. The mask layer 130 may be a DBR or an ODR layer. The first and second layers 132 and 134 may have different refractive indices from each other and may be formed of, for example, SiO₂ and TiO₂.

Referring to FIG. 3C, a mold layer 135 may be formed on the mask layer 130, and a plurality of first openings H1 may be formed in the mask layer 130 and the mold layer 135.

First, the mold layer 135 may be formed on the mask layer 130 and the mask layer 130 and the mold layer 135 may be patterned using a mask pattern to form a plurality of first openings H1. The mask layer 130 and the mold layer 135 may be formed of materials whose etching rates are different under particular etching conditions, and thus, an etching process may be controlled when the plurality of first openings H1 are formed. In detail, the first layer 132 (refer to FIG. 3B), the uppermost layer, among the plurality of layers constituting the mask layer 130, and the mold layer 135 may be formed of different materials, and, for example, the first layer 132 may be formed of TiO₂ and the mold layer 135 may be formed of SiO₂.

The sum of thicknesses of the mask layer 130 and the mold layer 135 may be designed in consideration of an intended height of the light emitting nanostructures 140 (refer to FIG. 1). Also, the size of the plurality of first openings H1 may be designed in consideration of a size of the light emitting nanostructures 140.

Referring to FIG. 3D, a first conductivity-type semiconductor may be grown on the exposed regions of the first conductivity-type semiconductor base layer 120 such that the plurality of first openings H1 are filled, thus forming a plurality of first conductivity-type semiconductor cores 142a.

The first conductivity-type semiconductor cores 142a may be formed of, for example, an n-type nitride semiconductor, and may be formed of a material identical to a material of the first conductivity-type semiconductor base layer 120. The first conductivity-type semiconductor core 142a may be formed using metal-organic chemical vapor deposition (MOCVD) or molecular beam epitaxy (MBE).

Referring to FIG. 3E, the mold layer 135 may be removed to expose the lateral surfaces of the plurality of first conductivity-type semiconductor cores 142a, and an active layer 144 and a second conductivity-type semiconductor layer 146 may be formed.

First, the mold layer 135 may be selectively removed with respect to the mask layer 130 and the first conductivity-type semiconductor cores 142a to leave the mask layer 130. The removing of the mold layer 135 may be performed by a wet etching process, for example. The mask layer 130 may prevent the active layer 144 and the second conductivity-type semiconductor layer 146 from being connected to the first conductivity-type semiconductor base layer 120 in a follow-up process.

After the mold layer 135 is removed, a heat-treatment process may be performed to convert crystal planes of the first conductivity-type semiconductor cores 142a into stable faces that are advantageous to crystal growth, such as semi-polar or non-polar crystal planes. Thus, a width of the first conductivity-type semiconductor cores 142 may be greater than a width of the plurality of first openings H1, and crystallinity of the first conductivity-type semiconductor cores 142 may be increased through regrowth. However, this process may be omitted in consideration of the shape of the plurality of first openings H1 and a growth shape of the first conductivity-type semiconductor cores 142 based on the shape of the plurality of first openings H1.

Thereafter, the active layer 144 and the second conductivity-type semiconductor layer 146 may be sequentially grown on surfaces of the first conductivity-type semiconductor cores 142. Accordingly, the light emitting nanostructures 140 having a core-shell structure may be formed. As described above, m planes and r planes of the first conductivity-type semiconductor cores 142 may have different thicknesses from each other according to a deposition method.

Also, according to an exemplary embodiment of the present inventive concept, an electric charge blocking layer (not shown) may be formed on the active layer 144. The electric charge blocking layer may prevent electrical charges injected from the first conductivity-type semiconductor core 142 from being transferred to the second conductivity-type semiconductor layer 146, rather than being used for electron-hole recombination in the active layer 144. The electric charge blocking layer may include a material having band gap energy greater than band gap energy of the active layer 144. For example, the electric charge blocking layer may include AlGaN or AlInGaN.

Referring to FIG. 3F, a transparent electrode layer 150 and a filler layer 160 may be formed on the second conductivity-type semiconductor layer 146.

The transparent electrode layer 150 may extend to cover upper surfaces of the mask layer 130 between adjacent light emitting nanostructures 140 and may be formed as a monolayer on the plurality of light emitting nanostructures 140.

Thereafter, the filler layer 160 may be formed on the transparent electrode layer 150. According to an exemplary embodiment of the present inventive concept, the filler layer 160 may be formed as a plurality of layers, and in this case, the plurality of layers may be formed of different materials, respectively, or when the plurality of layers are formed of the same material, the layers may be formed through different deposition processes.

Referring to FIG. 3G, a portion of the filler layer 160 may be removed and a preliminary contact portion 183P may be formed.

First, a process of removing the filler layer 160 in a region in which the first electrode 180 (refer to FIG. 1) is to be formed. The removing process may be performed using the transparent electrode layer 150 as an etch stop layer. Next, a material for forming the contact portion 183 (refer to FIG. 1) is deposited to form the preliminary contact portion 183P. According to an exemplary embodiment of the present inventive concept, like the semiconductor light emitting device 100a of FIG. 2, the boundary between the preliminary contact portion 183P and the filler layer 160 may be placed on the light emitting nanostructure 140, and in this case, a side wall of the preliminary contact portion 183P may be formed along the transparent electrode layer 150 on the light emitting nanostructure 140.

The preliminary contact portion 183P may be formed of a conductive material having excellent adhesive strength with respect to the transparent electrode layer 150. For example, the preliminary contact portion 183P may include chromium (Cr), and may be formed as multiple layers such as Cr/Au, Cr/Ni, or Cr/Al.

Referring to FIG. 3H, a process of reducing a thickness of the substrate 101 is performed, and a second opening H2 may be formed. FIG. 3H illustrates a structure in which the configuration of FIG. 3G is rotated by 180 degrees.

The substrate 101 may be reduced in thickness to reduce a thickness of a semiconductor device. When the substrate 101 is formed as a silicon (Si) substrate, a thickness of the substrate 101 may be easily reduced through a planarization process such as chemical mechanical polishing (CMP) process. The substrate 101 may have a second thickness T2 and the second thickness T2 may be smaller than the initial first thickness T1 (refer to FIG. 3A). The second thickness T2 may have a thickness of 100 μm or less, for example, a thickness of tens of micrometers.

Next, a portion of the substrate 101, where the second electrode 190 (refer to FIG. 1) is to be formed, may be removed to form the second opening H2 exposing the first conductivity-type semiconductor base layer 120. During this process, the substrate 101 may be etched using a hard mask layer, for example, a patterned silicon oxide layer. According to an exemplary embodiment of the present inventive concept, regarding the second opening H2, a recess having a predetermined depth may be formed in the first conductivity-type semiconductor base layer 120. When the substrate 101 is a silicon substrate, the substrate 101 may be easily processed, relative to a sapphire substrate, and thus, facilitating an etching process in this stage.

Referring to FIG. 3I, the first insulating layer 174 and the second through portion 195 may be formed.

First, the first insulating layer 174 may be formed on an exposed surface of the substrate 101, and a portion of the first insulating layer 174 may subsequently be removed from a lower surface of the second opening H2 to expose the first conductivity-type semiconductor base layer 120.

Next, a conductive material may be deposited to form a second through portion 195. The second through portion 195 may be formed through, for example, electroplating or electroless plating. The second through portion 195 may be electrically isolated from the substrate 101 by the first insulating layer 174.

Referring to FIG. 3J, a third opening H3 may be formed in a region in which the preliminary contact portion 183P is formed.

The third opening H3 may be formed by removing at least a portion of the substrate 101, the first conductivity-type semiconductor base layer 120, and the light emitting nanostructures 140 surrounded by the preliminary contact portion 183P. During this process, the preliminary contact portion 183P may serve as an etch stop layer. The preliminary contact portion 183P having a relatively lesser thickness between the light emitting nanostructures 140 may be removed together to form a contact portion 183. A thickness of the contact portion 183 below the third opening H3 may remain thicker than a thickness of the contact portion 183 on lateral surfaces of the third opening H3 according to a depth of the third opening H3. However, according to an exemplary embodiment of the present inventive concept, the preliminary contact portion 183P between the light emitting nanostructures 140 may not be removed but remain. In this case, like the semiconductor light emitting device 100a of FIG. 2, a contact portion 185a having a size corresponding to a size of a light emitting nanostructure 140 may be formed in a follow-up process.

During the removing process, various etchants may be used depending on etched materials, and several operations may be sequentially performed. In particular, after the substrate 101 is etched, etching may be performed using Cl₂ plasma. Through this process, the contact portion 183 may be disposed on the lateral surfaces and lower surface of the third opening H3 below the transparent electrode layer 150 in FIG. 3J.

Referring to FIG. 3K, the second insulating layer 176 and the first through portion 185 may be formed.

First, the second insulating layer 176 may be formed within the third opening H3, and a portion of the second insulating layer 176 may be removed from a lower surface of the third opening H3 to expose the contact portion 183. The second insulating layer 176 may be formed on the substrate 101 and the first conductivity-type semiconductor base layer 120 within the third opening H3 to electrically isolate the first through portion 185 from the substrate 101 and the first conductivity-type semiconductor base layer 120. As illustrated in FIG. 3K, the second insulating layer 176 may also be formed on the second through portion 195, and a portion of the second insulating layer 176 may be removed to expose the second through portion 195.

FIG. 3K illustrates that the second insulating layer 176 extends to a lower side of the first conductivity-type semiconductor base layer 120, but the present inventive concept is not limited thereto. According to an exemplary embodiment of the present inventive concept, the second insulating layer 176 may only be formed on the side walls of the substrate 101 and the first conductivity-type semiconductor base layer 120.

Thereafter, a conductive material may be deposited to form the first through portion 185. The first through portion 185 may be formed through, for example, electroplating, electroless plating, or physical vapor deposition (PVD). During this process, a conductive material may also be deposited on the second through portion 195 to form a portion of the second through portion 195.

Referring to FIG. 3L, first and second bonding portions 187 and 197 may be formed to extend to one surface of the substrate 101.

The first and second bonding portions 187 and 197 may be formed to be connected to the first and second through portions 185 and 195, respectively, and thus, the first and second electrodes 180 and 190 may be finally formed. The first and second bonding portions 187 and 197 may be formed of a conductive material and include, for example, one or more of Ag, Al, Ni, Cr, Cu, Au, Pd, Pt, Sn, W, Rh, Ir, Ru, Mg, Zn, Ti, and an alloy material including the same.

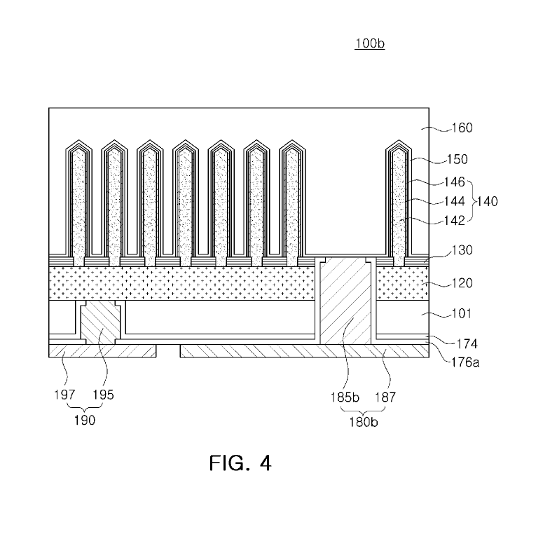

FIG. 4 is a cross-sectional view schematically illustrating a semiconductor light emitting device according to an exemplary embodiment of the present inventive concept.

Referring to FIG. 4, a semiconductor light emitting device 100b may include a substrate 101, and a first conductivity-type semiconductor base layer 120, a mask layer 130, a light emitting nanostructure 140, a transparent electrode layer 150, and a filler layer 160 formed on the substrate 101. The light emitting nanostructure 140 may include a first conductivity-type semiconductor core 142, an active layer 144, and a second conductivity-type semiconductor layer 146 grown on the first conductivity-type semiconductor base layer 120. The semiconductor light emitting device 100b may further include a first electrode 180b electrically connected to the second conductivity-type semiconductor layer 146, and a second electrode 190 electrically connected to the first conductivity-type semiconductor base layer 120 through the substrate 101.

In an exemplary embodiment of the present inventive concept, the first electrode 180b may include only a first through portion 185b and a first bonding portion 187, unlike the semiconductor light emitting device 100 according to the exemplary embodiment of FIG. 1. Namely, the contact portion 183 (refer to FIG. 1) may be omitted.

The first through portion 185b may extend from the first bonding portion 187 disposed on a lower surface of the substrate 101, penetrate through the substrate 101 and the first conductivity-type semiconductor base layer 120, and may be connected to the transparent electrode layer 150 in a contacting manner. Thus, the light emitting structure 140 may not be disposed on the first through portion 185b. According to an exemplary embodiment of the present inventive concept, a region in which the light emitting nanostructure 140 is not disposed may be smaller than that illustrated in FIG. 4, and thus, the width of the first through portion 185b may also be smaller.

Without forming the first opening H1 in the region in which first electrode 180b is to be formed during the manufacturing process described above with reference to FIG. 3C, the semiconductor light emitting device 100b according to an exemplary embodiment of the present inventive concept may be manufactured by forming the region of the transparent electrode layer 150 extending horizontally on the region during the process described above with reference to FIG. 3F. Also, the operation of forming the preliminary contact layer 183P in FIG. 3G may be omitted, and the semiconductor light emitting device 100b according to an exemplary embodiment of the present inventive concept may be manufactured by forming the third opening H3 such that only the substrate 101 and the first conductivity-type semiconductor base layer 120 are etched using the transparent electrode layer 150 as an etch stop layer in process described above with reference to FIG. 3J. Also, according to an exemplary embodiment of the present inventive concept, the order of forming the first and second electrodes 180b and 190 may be changed or the first and second electrodes 180b and 190 may be simultaneously formed. Accordingly, the order of dispositions of the first and second insulating layers 174 and 176a may also be changed.

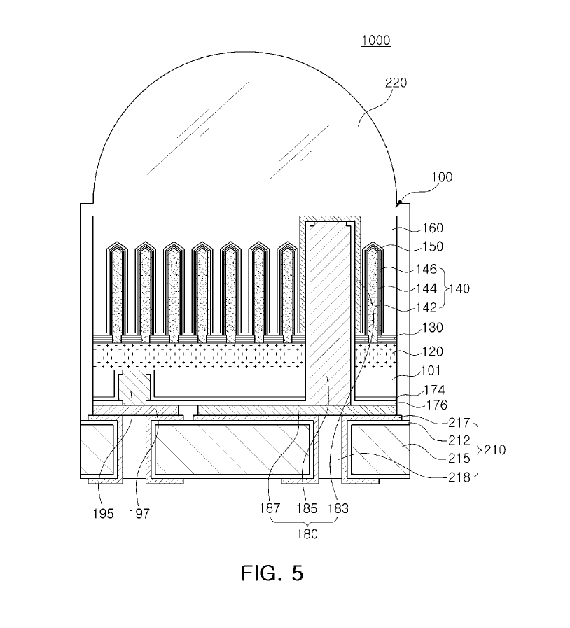

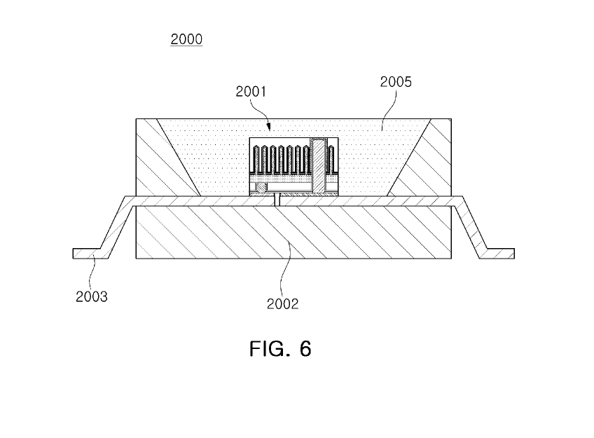

FIGS. 5 and 6 are views illustrating examples of packages employing a semiconductor light emitting device according to an exemplary embodiment of the present inventive concept.

Referring to FIG. 5, a semiconductor light emitting device package 1000 may include the semiconductor light emitting device 100 illustrated in FIG. 1, a package board 210, and an encapsulant 220. The semiconductor light emitting device package 1000 according to an exemplary embodiment of the present inventive concept may be a chip-scale package (CSP) and may be a wafer level package (WLP).

The semiconductor light emitting device 100 may be mounted such that the first and second electrodes 180 and 190 are connected to an electrode pattern 217 of the package board 210.

The package board 210 may include a body unit 215, an insulating layer 212 surrounding the body unit 215, and an electrode pattern 217 on the insulating layer 212. Also, a via hole 218 may be formed as penetrating through upper and lower surfaces of the package board 210. The via hole 218 may be formed of a conductive material, and as illustrated in FIG. 5, the electrode pattern 217 may extend to the interior of the via hole 218. The package board 210 may be provided as a board such as a printed circuit board (PCB), a metal-core printed circuit board (MCPCB), a metal printed circuit board (MPCB), a flexible printed circuit board (FPCB), or the like. The structure of the package board 210 may be formed to have a number of variations.

The encapsulant 220 may be formed to have a lens structure with an upper surface having a convex dome shape. However, according to an exemplary embodiment of the present inventive concept, the encapsulant 2003 may have a lens structure having a convex or concave surface to adjust a beam angle of light emitted through an upper surface of the encapsulant 220.

In an exemplary embodiment of the present inventive concept, the semiconductor light emitting device package 1000 may include the semiconductor light emitting device 100 illustrated in FIG. 1. However, according to an exemplary embodiment of the present inventive concept, the semiconductor light emitting device package 1000 may include the semiconductor light emitting device 100a or 100b according to other exemplary embodiments of the present inventive concept described above with reference to FIGS. 2 and 4.

In the semiconductor light emitting device package 1000 according to an exemplary embodiment of the present inventive concept, the semiconductor light emitting device 100 may be mounted on the package board 210 without wire bonding, simplifying processes, and a defect due to wire bonding may be prevented in advance. Also, a chip-scale miniaturized semiconductor light emitting device package 1000 may be implemented.

Referring to FIG. 6, a semiconductor light emitting device package 2000 may include a semiconductor light emitting device 2001, a package body 2002, and a pair of lead frames 2003. The semiconductor light emitting device 2001 may be mounted on the lead frame 2003 and electrically connected to the lead frame 2003. According to an exemplary embodiment of the present inventive concept, the semiconductor light emitting device 2001 may be mounted on a different region, for example, on the package body 2002, rather than on the lead frame 2003. The package body 2002 may have a cup shape to improve reflectivity efficiency of light. An encapsulant 2005 formed of a light-transmissive material may be formed in the reflective cup to encapsulate the semiconductor light emitting device 2001.

In an exemplary embodiment of the present inventive concept, the semiconductor light emitting device package 2000 may include the semiconductor light emitting device 2001 having a structure similar to that of the semiconductor light emitting device 100 illustrated in FIG. 1. In detail, the semiconductor light emitting device 100 of FIG. 1 may be mounted in a flipchip structure in which both the first and second electrodes 180 and 190 are disposed downwardly. However, according to an exemplary embodiment of the present inventive concept, the semiconductor light emitting device package 2000 may include the semiconductor light emitting device 100a or 100b according to other exemplary embodiments of the present inventive concept described above with reference to FIGS. 2 and 4.

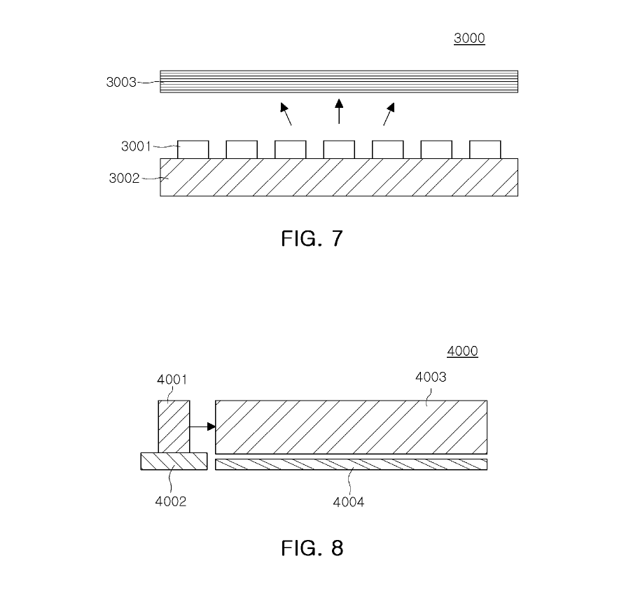

FIGS. 7 and 8 are examples of backlight units employing a semiconductor light emitting device according to an exemplary embodiment of the present inventive concept.

Referring to FIG. 7, a backlight unit 3000 may include light sources 3001 mounted on a substrate 3002 and one or more optical sheets 3003 disposed above the light sources 3001. The semiconductor light emitting device package having the structure described above with reference to FIGS. 5 and 6 or a structure similar thereto may be used as the light sources 3001. Alternatively, a semiconductor light emitting device may be directly mounted on the substrate 3002 (a so-called COB type) and used.

Unlike the backlight unit 3000 in FIG. 7 in which the light sources 3001 emit light toward an upper side where a liquid crystal display is disposed, a backlight unit 4000 as another example illustrated in FIG. 8 may be configured such that a light source 4001 mounted on a substrate 4002 emits light in a lateral direction, and the emitted light may be made to be incident to a light guide plate 4003 so as to be converted into a surface light source. Light, passing through the light guide plate 4003, is emitted upwards, and in order to enhance light extraction efficiency, a reflective layer 4004 may be disposed on a lower surface of the light guide plate 4003. The semiconductor light emitting device package having the structure described above with reference to FIGS. 5 and 6 or a structure similar thereto may be used as the light source 4001. Alternatively, a semiconductor light emitting device may be directly mounted on the substrate 4002 (a so-called COB type) and used.

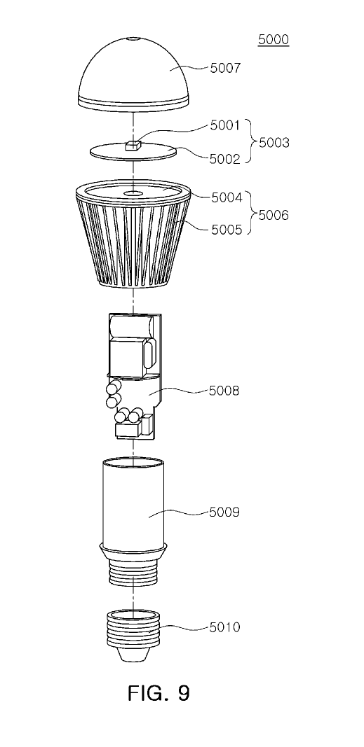

FIG. 9 is a view illustrating an example of a lighting device employing a semiconductor light emitting device according to an exemplary embodiment of the present inventive concept.

Referring to the exploded perspective view of FIG. 9, a lighting device 5000 is illustrated as, for example, a bulb-type lamp and may include a light emitting module 5003, a driving unit 5008, and an external connection unit 5010. Also, the lighting device 5000 may further include external structures such as external and internal housings 5006 and 5009 and a cover unit 5007. The light emitting module 5003 may include a semiconductor light emitting device 5001 having a structure identical or similar to those of the semiconductor light emitting devices 100, 100a, and 100b described above with reference to FIGS. 1, 2, and 4 and a circuit board 5002 on which the semiconductor light emitting device 5001 is mounted. In an exemplary embodiment of the present inventive concept, it is illustrated in FIG. 9 that a single semiconductor light emitting device 5001 is mounted on the circuit board 5002, but a plurality of semiconductor light emitting devices may be installed as needed. Also, the semiconductor light emitting device 5001 may be manufactured as a package and subsequently mounted, rather than being directly mounted on the circuit board 5002.

The external housing 5006 may serve as a heat dissipation unit and may include a heat dissipation plate 5004 disposed to be in direct contact with the light emitting module 5003 to enhance heat dissipation and heat dissipation fins 5005 surrounding the lateral surfaces of the lighting device 5000. Also, the cover unit 5007 may be installed on the light emitting module 5003 and have a convex lens shape. The driving unit 5008 may be installed in the internal housing 5009 and connected to the external connection unit 5010 having a socket structure to receive power from an external power source. Also, the driving unit 5008 may convert power into an appropriate current source for driving the semiconductor light emitting device 5001 of the light emitting module 5003, and provide the same. For example, the driving unit 5008 may be configured as an AC-DC converter, a rectifying circuit component, or the like.

Also, although not shown, the lighting device 5000 may further include a communications module.

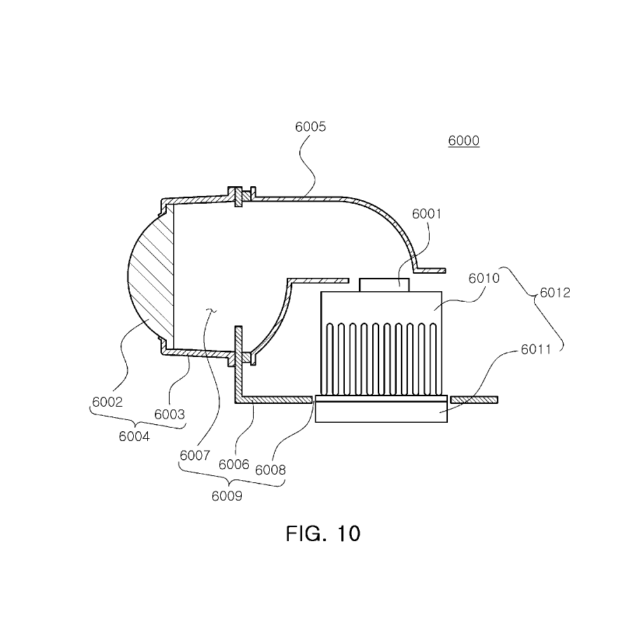

FIG. 10 is a view illustrating an example of a headlamp employing a semiconductor light emitting device according to an exemplary embodiment of the present inventive concept.

Referring to FIG. 10, a headlamp 6000 used as a vehicle lamp, or the like, may include a light source 6001, a reflective unit 6005, and a lens cover unit 6004. The lens cover unit 6004 may include a hollow guide 6003 and a lens 6002. The light source 6001 may include at least one of semiconductor light emitting device packages of FIGS. 5 and 6. The headlamp 6000 may further include a heat dissipation unit 6012 outwardly dissipating heat generated by the light source 6001. In order to effectively dissipate heat, the heat dissipation unit 6012 may include a heat sink 6010 and a cooling fan 6011. Also, the headlamp 6000 may further include a housing 6009 fixedly supporting the heat dissipation unit 6012 and the reflective unit 6005, and the housing 6009 may have a body unit 6006 and a central hole 6008 formed in one surface thereof, in which the heat dissipation unit 6012 is coupled. Also, the housing 6009 may have a front hole 6007 formed in the other surface integrally connected to the one surface and bent in a right angle direction. The reflective unit 6005 is fixed to the housing 6009 such that light generated by the light source 6001 is reflected thereby to pass through the front hole 6007 to be output outwardly.

As set forth above, according to exemplary embodiments of the present inventive concept, a semiconductor light emitting device in which loss of a light emitting area is minimized and heat may be easily dissipated by disposing electrodes to face a board may be provided. Also, a semiconductor light emitting device package in which a semiconductor light emitting device is mounted on a package board in a flipchip manner, simplifying processes, and which is thus miniaturized may be provided.

Advantages and effects of the present inventive concept are not limited to the foregoing content and any other technical effects not mentioned herein may be easily understood by a person skilled in the art from the foregoing description.

While exemplary embodiments of the present inventive concept have been shown and described above, it will be apparent to those skilled in the art that modifications and variations could be made without departing from the spirit and scope of the present inventive concept as defined by the appended claims.

What is claimed is:

1. A semiconductor light emitting device, comprising:
a substrate;
a first conductivity-type semiconductor base layer disposed on the substrate;
a plurality of light emitting nanostructures disposed to be spaced apart from one another on the first conductivity-type semiconductor base layer and including a first conductivity-type semiconductor core, an active layer, and a second conductivity-type semiconductor layer, respectively;
a transparent electrode layer disposed on the second conductivity-type semiconductor layer and between the plurality of light emitting nanostructures; and
a first electrode electrically connected to the second conductivity-type semiconductor layer by penetrating the substrate.

2. The semiconductor light emitting device of claim 1, wherein the first electrode extends between the plurality of light emitting nano structures from a lower surface of the substrate.

3. The semiconductor light emitting device of claim 2, wherein the first electrode comprises:
a through portion penetrating the substrate, the first conductivity-type semiconductor base layer, the transparent electrode layer, and a portion of the plurality of light emitting nanostructures; and
a contact portion connecting the through portion and the transparent electrode layer.

4. The semiconductor light emitting device of claim 3, wherein the contact portion surrounds the through portion between the plurality of light emitting nanostructures on an upper side of the transparent electrode layer.

5. The semiconductor light emitting device of claim 3, wherein the through portion is electrically isolated from the substrate and the first conductivity-type semiconductor base layer by an insulating layer.

6. The semiconductor light emitting device of claim 5, wherein the insulating layer surrounds lateral surfaces of the through portion.

7. The semiconductor light emitting device of claim 1, wherein the first electrode is in contact with the transparent electrode layer by penetrating the substrate and the first conductivity-type semiconductor base layer.

8. The semiconductor light emitting device of claim 7, wherein the plurality of light emitting nanostructures are not disposed on the first electrode and the transparent electrode layer is disposed to be flat on the first electrode.

9. The semiconductor light emitting device of claim 1, further comprising a second electrode connected to the first conductivity-type semiconductor base layer by penetrating the substrate.

10. The semiconductor light emitting device of claim 1, further comprising a mask layer disposed on the first conductivity-type semiconductor base layer and having a plurality of openings exposing the first conductivity-type semiconductor base layer,
wherein the mask layer is a distributed Bragg Reflector (DBR) layer.

11. The semiconductor light emitting device of claim 1, wherein the substrate is a silicon (Si) substrate.

12. The semiconductor light emitting device of claim 1, further comprising a filler layer filling spaces between the plurality of light emitting nanostructures,
wherein the first electrode penetrates the filler layer, and an upper surface of the first electrode is substantially coplanar with an upper surface of the filler layer.

13. A semiconductor light emitting device package, comprising:
a package board; and
a semiconductor light emitting device disposed on the package board,
wherein the semiconductor light emitting device comprises:
a substrate;
a first conductivity-type semiconductor base layer disposed on the substrate;
a plurality of light emitting nanostructures disposed to be spaced apart from one another on the first conductivity-type semiconductor base layer and including a first conductivity-type semiconductor core, an active layer, and a second conductivity-type semiconductor layer, respectively;
a transparent electrode layer disposed on the second conductivity-type semiconductor layer and between the plurality of light emitting nanostructures;
a first electrode electrically connected to the second conductivity-type semiconductor layer by penetrating the substrate; and
a second electrode electrically connected to the first conductivity-type semiconductor base layer by penetrating the substrate,
wherein the semiconductor light emitting device is disposed on the package board such that a light emitting surface faces upwards and the first and second electrodes are connected to the package board.

14. The semiconductor light emitting device package of claim 13, further comprising a lens encapsulating the semiconductor light emitting device.

15. The semiconductor light emitting device package of claim 13, wherein the package board includes at least one via hole.

16. A semiconductor light emitting device package, comprising:
a package body;
a lead frame; and
a semiconductor light emitting device disposed on the lead frame in the package body and electrically connected to the lead frame,
wherein the semiconductor light emitting device comprises:
a substrate;
a first conductivity-type semiconductor base layer disposed on the substrate;
a plurality of light emitting nanostructures disposed to be spaced apart from one another on the first conductivity-type semiconductor base layer and including a first conductivity-type semiconductor core, an active layer, and a second conductivity-type semiconductor layer, respectively;
a transparent electrode layer disposed on the second conductivity-type semiconductor layer and between the plurality of light emitting nanostructures;
a first electrode electrically connected to the second conductivity-type semiconductor layer by penetrating the substrate; and
a second electrode electrically connected to the first conductivity-type semiconductor base layer by penetrating the substrate,
wherein the semiconductor light emitting device is disposed in a flipchip structure in which both the first and second electrodes are disposed downwardly on the lead frame.

17. The semiconductor light emitting device package of claim 16, wherein the lead frame includes a pair of lead frames electrically connected the first and second electrodes of the semiconductor light emitting device, respectively.

18. The semiconductor light emitting device package of claim 16, further comprising an encapsulant including a light-transmissive material, wherein:
the package body has a cup shape to reflect light emitted from the semiconductor light emitting device, and
the encapsulant is disposed in the cup shape to encapsulate the semiconductor light emitting device.

19. The semiconductor light emitting device of claim 3, wherein an upper surface of the through portion of the first electrode is above an upper surface of the light emitting nanostructures.

20. The semiconductor light emitting device of claim 3, wherein an upper surface of the through portion of the first electrode is at the same vertical level as a vertical level of an upper surface of the light emitting nanostructures.
